(19) United States
(12) Patent Application Publication
(10) Pub. No.: US 2007/0094569 A1
(43) Pub. Date: Apr. 26, 2007

(54) Determining hard errors vs. soft errors in memory

(76) Inventors: Larry J. Thayer, Fort Collins, CO (US); Andrew C. Walton, Rocklin, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/257,958

(22) Filed: Oct. 24, 2005

(51) Int. Cl. G11C 29/00

(52) U.S. Cl. 714/763

(57) ABSTRACT

In a preferred embodiment, the invention provides a method for determining soft and hard errors in memory. First one or more errors are detected in memory. Next correct data is written back to the memory locations were the error(s) were detected. Data is then read from the memory locations where the correct data was written. If the data that was read is correct, the memory locations where error(s) were detected are written to a register block indicating a soft error. If the data that was read is not correct, the memory locations where error(s) were detected are written to a register block indicating a hard error.

### FIELD OF THE INVENTION

This invention relates generally to memory design. More particularly, this invention relates to determining whether errors in memory are soft errors or hard errors.

### BACKGROUND OF THE INVENTION

High-energy neutrons lose energy in materials mainly through collisions with silicon nuclei that lead to a chain of secondary reactions. These reactions deposit a dense track of electron-hole pairs as they pass through a p-n junction. Some of the deposited charge will recombine, and some will be collected at the junction contacts. When a particle strikes a sensitive region of a latch, the charge that accumulates could exceed the minimum charge that is needed to “flip” the value stored on the latch, resulting in a soft error.

The smallest charge that results in a soft error is called the critical charge of the latch. The rate at which soft errors occur (SER) is typically expressed in terms of failures in time (FIT).

A common source of soft errors are alpha particles which may be emitted by trace amounts of radioactive isotopes present in packing materials of integrated circuits. “Bump” material used in flip-chip packaging techniques has also been identified as a possible source of alpha particles.

Other sources of soft errors include high-energy cosmic rays and solar particles. High-energy cosmic rays and solar particles react with the upper atmosphere generating high-energy protons and neutrons that shower to the earth. Neutrons can be particularly troublesome as they can penetrate most man-made construction (some number of neutrons will pass through five feet of concrete). This effect varies with both latitude and altitude. In London, the effect is two times worse than on the equator. In Denver, Colo. with its mile-high altitude, the effect is three times worse than at sea-level San Francisco. In a commercial airplane, the effect can be 100-800 times worse than at sea-level.

A hard error, also called a repeatable error, consistently returns incorrect data. For example, a bit may be such that it always returns a zero regardless of whether a zero or one is written to it. Hard errors are relatively easy to diagnose because they are consistent and repeatable.

There is a need in the art for a memory controller to identify hard and soft errors in memory devices. An embodiment of this invention identifies hard and soft errors in memory devices.

### BRIEF DESCRIPTION OF THE DRAWINGS

FIG. 1 is flow chart showing an embodiment of a method for determining whether error(s) are soft error(s) or hard error(s).

FIG. 2 is a block diagram of an embodiment of a system for determining whether error(s) are soft error(s) or hard error(s).

FIG. 3 is a block diagram of a computer system with an embodiment of a system for determining whether error(s) are soft error(s) or hard error(s).

### DETAILED DESCRIPTION OF THE PREFERRED EMBODIMENT

An embodiment of this invention determines whether errors detected in memory are hard errors or soft errors. Memory includes but is not limited to DRAMs (dynamic random access memory), SRAMs (static random access memory), and latches. A common function performed by memory controllers is scrubbing. One type of scrubbing, among others relevant to this invention, includes “reactive scrubbing.”

One application of reactive scrubbing detects errors in data read from DRAM memory using an error-correction algorithm and then writes back corrected data to the location where errors where detected in the DRAM memory. Error-correction algorithms include but are not limited to Hamming, Reed-Solomon, Reed-Muller, and convolution codes. Current reactive scrubbing techniques do not indicate whether the errors were soft errors or hard errors.

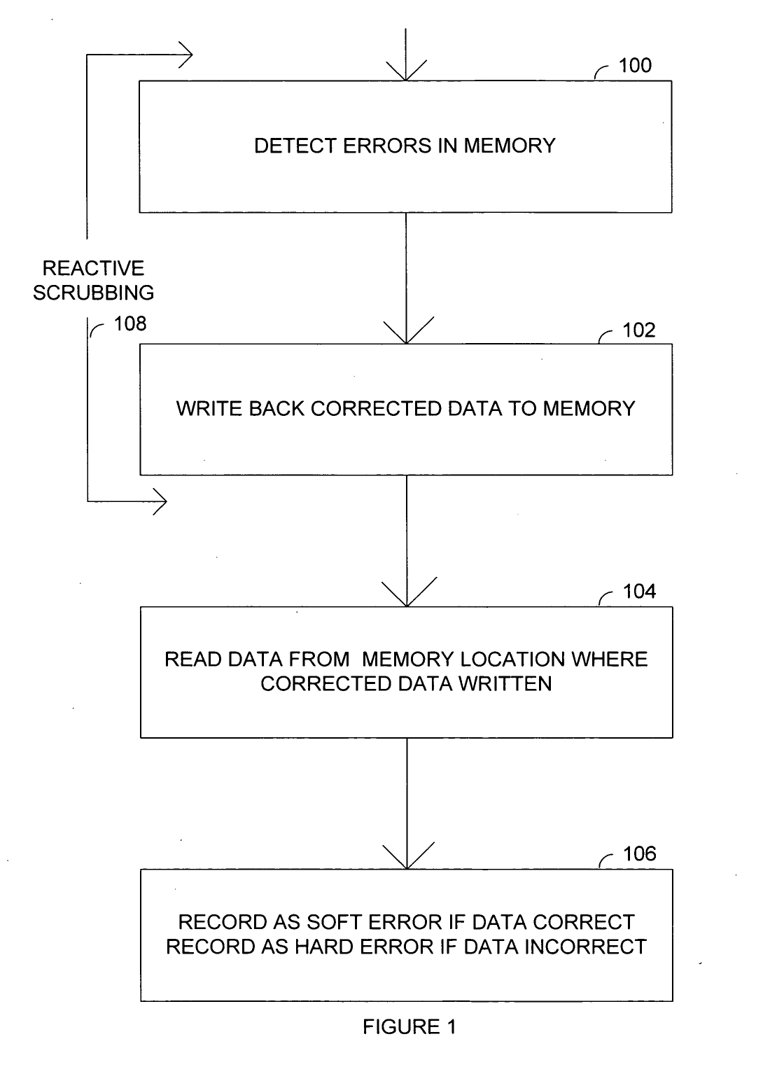

FIG. 1 is flow chart showing an embodiment of a method for determining whether errors are soft errors or hard errors. The first step, 100, of this embodiment of determining whether errors are soft errors or hard errors, detects errors in memory using an error-correction code. The second step, 102, of this embodiment of determining whether errors are soft errors or hard errors, writes back corrected data, one or more bits, to the memory location where errors were detected. Applying steps one, 100, and two, 102, are considered in the art to be part of reactive scrubbing.

The third step, 104, of this embodiment of determining whether errors are soft errors or hard errors, reads data, one or more bits, from the memory location where corrected data was written. The fourth step, 106, of this embodiment of determining whether errors are soft errors or hard errors, records the location where one or more errors were detected as soft errors, in a register block if the data read in step 3, 104, is correct. The fourth step, 106, of this embodiment of determining whether errors are soft errors or hard errors, records the location where one or more errors were detected as hard errors, in a register block if the data read in step 3, 104, is incorrect.

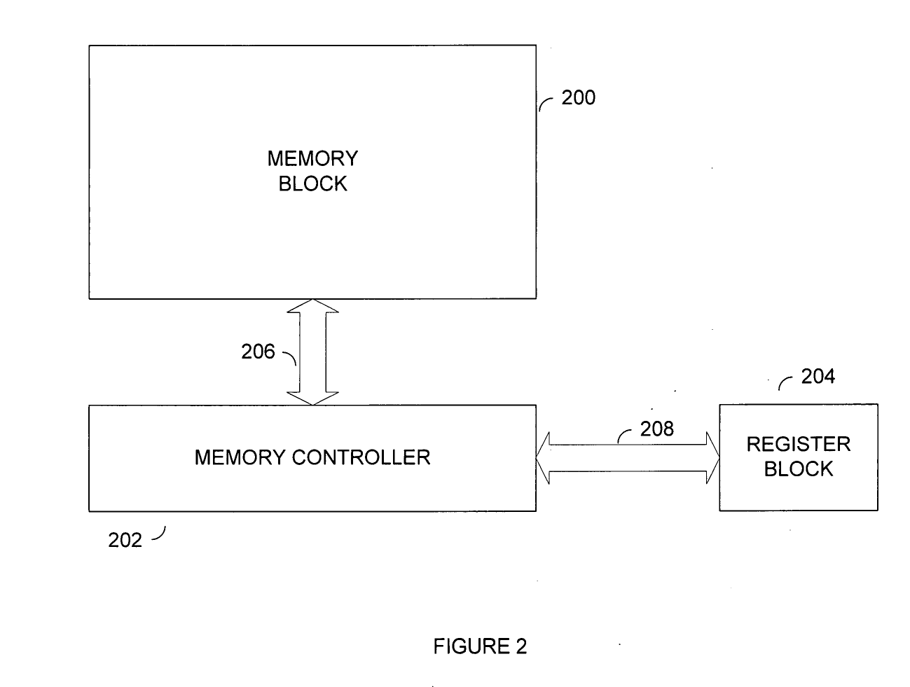

FIG. 2 is a block diagram of an embodiment of a system for determining whether errors are soft errors or hard errors. In this embodiment a memory block is represented by block 200. In this embodiment a memory controller is represented by block 202. In this embodiment a register block is represented by block 204. In this embodiment an electrical connection is represented by a double-headed arrow 206. In this embodiment an electrical connection is represented by a double-headed arrow 208.

The memory controller, 202, in one embodiment of the invention in FIG. 2 reactively scrubs data in memory block 200. One application of reactive scrubbing detects errors in data read from DRAM memory through the electrical connection 206 using an error-correction algorithm and then writes corrected data back through the electrical connection 206 to the location where errors where detected in the memory block 200. After writing corrected data back to the location where errors where detected in the memory block 200, the same location in memory is read. If the data read back from the memory block 200 is the same data written previously, the memory locations where error(s) were detected are written to a register block, 204, through the electrical connection, 208, indicating a soft error. If the data read back from memory block 200 is not the same data written previously, the memory locations where error(s) were detected are written to a register block indicating a hard error. Other error-correction algorithms including Hamming, Reed-Solomon, Reed-Muller, and convolution codes may be used. Memory block 200 may include but is not limited to DRAMs, SRAMs, and latches.

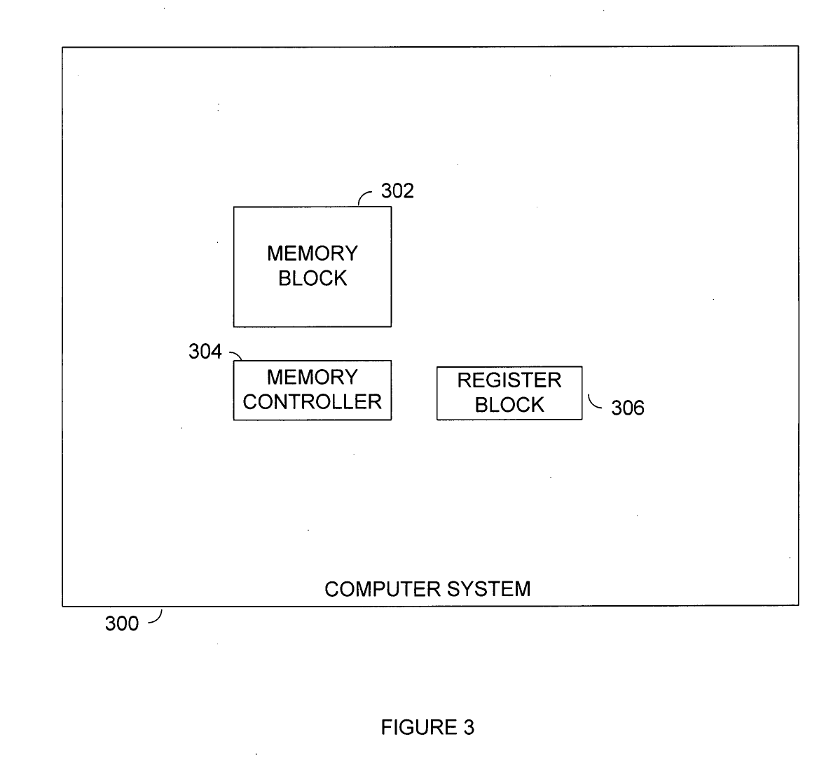

FIG. 3 is a block diagram of a computer system with an embodiment of a system for determining whether errors are soft errors or hard errors. The computer system, 300, contains at least one memory block, 302, at least one memory controller, 304, and at least one register block, 306. The memory controller, 304 reactively scrubs data in memory block 302. One application of reactive scrubbing detects errors in data read from memory block 302 using an error-correction algorithm and then writes corrected data back to the location where errors where detected in the memory block 302. After writing corrected data back to the location where errors where detected in the memory block 302, the same location in memory is read. If the data read back from the memory block 302 is the same data written previously, the location where the errors were detected are written into register block 306 indicating a soft error. If the data read back from memory block 302 is not the same data written previously, the location where the errors were detected are written into register block 306 indicating a hard error. Other error-correction algorithms including Hamming, Reed-Solomon, Reed-Muller, and convolution codes may be used. Memory block 302 may include but is not limited to DRAMs, SRAMs, and latches.

The foregoing description of the present invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1) A method for determining soft and hard errors in memory comprising:
a) detecting one or more errors in the memory;
b) writing correct data back to memory locations where the error(s) were detected;
c) reading data from the memory locations where the correct data was written;
d) if the data read in step (c) is correct, the memory locations where error(s) were detected are written to a register block indicating a soft error;
e) if the data read in step (c) is not correct, the memory locations where error(s) were detected are written to a register block indicating a hard error.

2) The method as in claim 1 wherein an error-correction algorithm is used to detect one or more errors in the memory.

3) The method as in claim 2 wherein the error-correction algorithm is a Hamming code.

4) The method as in claim 2 wherein the error-correction algorithm is a Reed-Solomon code.

5) The method as in claim 2 wherein the error-correction algorithm is a Reed-Muller code.

6) The method as in claim 2 wherein the error-correction algorithm is a convolution code.

7) The method as in claim 1 wherein steps (a) and (b) are accomplished using reactive scrubbing.

8) A system for determining soft and hard errors in a memory block comprising:
a) a memory controller;
b) a register block;
c) a first electrical connection;
d) a second electrical connection;
e) wherein one or more errors in the memory block are detected by the memory controller;
f) wherein the memory controller writes corrected data back to locations where one or more errors were detected through the first electrical connection;
g) wherein the memory controller reads data back from the locations where the corrected data was written through the first electrical connection;
h) such that if the data read by the memory controller is correct, the memory locations where error(s) were detected are written to the register block indicating a soft error through the second electrical connection;
i) such that if the data read by the memory controller is not correct, the memory locations where error(s) were detected are written to the register block indicating a hard error through the second electrical connection.

9) The system as in claim 8 wherein the memory block is a DRAM.

10) The system as in claim 8 wherein the memory block is an SRAM.

11) The system as in claim 8 wherein the memory block is a register array.

12) A computer system comprising:
a) at least one memory block;
b) at least one memory controller;
c) at least one register block;
d) wherein one or more errors in a memory block are detected by a memory controller;
e) wherein the memory controller writes corrected data back to locations in the memory block where one or more errors were detected;
f) wherein the memory controller reads data back from the locations where the corrected data was written;
g) such that if the data read by the memory controller is correct, the memory locations where error(s) were detected are written to a register block indicating a soft error;
h) such that if the data read by the memory controller is not correct, the memory locations where error(s) were detected are written to a register block indicating a hard error.

13) The computer system as in claim 12 wherein the memory block is a DRAM.

14) The computer system as in claim 12 wherein the memory block is an SRAM.

15) The computer system as in claim 12 wherein the memory block is a register array.

16) A system for determining soft and hard errors in a memory block comprising:
a) a first means for storing electronic data;
b) a means for detecting and correcting data errors in the first means for storing electronic data;
c) a second means for storing electronic data;
d) such that the means for detecting and correcting data errors writes correct data into the first means for storing electronic data when one or more errors are detected in the first means for storing electronic data;
e) such that the means for detecting and correcting data errors reads data from the first means for storing electronic data from the locations where one or more errors were detected;
f) such that if the data read by the means for detecting and correcting data errors is correct, the memory locations where error(s) were detected are written to the second means for storing electronic data indicating a soft error;
g) such that if the data read by the means for detecting and correcting data errors is not correct, the memory locations where error(s) were detected are written to the second means for storing electronic data indicating a hard error.
